(19) United States
(12) Patent Application Publication
(10) Pub. No.: US 2016/0043227 A1
(43) Pub. Date: Feb. 11, 2016

(54) THIN FILM TRANSISTOR AND MANUFACTURING METHOD THEREOF

(71) Applicant: PEKING UNIVERSITY SHENZHEN GRADUATE SCHOOL, Shenzhen, Guangdong (CN)

(72) Inventors: Shengdong Zhang, Shenzhen (CN); Yang Shao, Shenzhen (CN); Xin He, Shenzhen (CN); Xiang Xiao, Shenzhen (CN)

(21) Appl. No.: 14/762,521

(22) PCT Filed: Nov. 11, 2013
(86) PCT No.: PCT/CN2013/086814

§ 371 Date: Jul. 22, 2015

(30) Foreign Application Priority Data
Apr. 15, 2013 (CN) 201310130474.3

(51) Int. Cl. H01L 29/786; H01L 21/477; H01L 21/461; H01L 21/465; H01L 29/66; H01L 29/423

(52) U.S. Cl. CPC H01L 29/7869; H01L 29/66969; H01L 29/42384; H01L 21/461; H01L 21/465; H01L 21/477

(57) ABSTRACT

A method of manufacturing a thin film transistor, comprising: forming a gate electrode (2) on a first surface of a substrate (1); forming on the first surface of the substrate a gate dielectric layer (3) covering the gate electrode; forming a metal oxide semiconductor layer (4) on the gate dielectric layer; processing the metal oxide semiconductor layer to form a channel region (5) exposed thereon; anode-oxidizing the channel region, such that the channel region has a first carrier concentration; and conducting photolithography and etching the metal oxide semiconductor layer to form an active region, the active region comprising the channel region, and a source region (6) and a drain region (7) located at the two sides of the channel region and having a second carrier concentration, the first carrier concentration being lower than the second carrier concentration. The source region, the drain region and the channel region of a thin film transistor manufactured using the above method are located on the same film layer, and the channel region has a carrier concentration lower than the carrier concentration of the source region and the drain region.

### BACKGROUND

1. Technical Field

The present invention relates to a method of manufacturing a thin film transistor, and a thin film transistor manufactured according to the manufacturing method.

2. Related Art

A flat panel display technology has developed to a mainstream technology of information display. For a flat panel display, whether it is a currently dominating liquid crystal display, an Organic Light Emitting Diode (OLED) display that may become a mainstream of the next generation, or a future flexible-substrate display, if large-size and high-definition display is to be implemented, a thin film transistor must be used as a switch control element or an integrated element of a peripheral drive circuit. Currently, widely used thin film transistors are mainly conventional silicon-based thin film transistors, for example, amorphous-silicon thin film transistors and polycrystalline silicon thin film transistors.

However, along with the continuous development of the flat panel display technology, the silicon-based thin film transistors can no longer meet requirements of people. The amorphous-silicon thin film transistor has defects such as a low mobility and easy performance degradation, and is greatly limited in applications in terms of OLED pixel drive, LCD and OLED peripheral drive circuit integration, and the like. The polycrystalline silicon thin film transistor has a high processing temperature, high manufacturing cost and poor uniformity of device performance, and therefore, it is not suitable for a large-size flat panel display application. Therefore, development of a more advanced thin film transistor technology is in urgent need for the sake of development of the flat panel display technology. The novel thin film transistor technologies currently in research and development mainly include a metal oxide thin film transistor, a microcrystalline silicon thin film transistor, an organic semiconductor thin film transistor, and the like.

The metal oxide thin film transistor has a low processing temperature, low processing cost, high carrier mobility, and uniform and stable device performance, not only combines advantages of the amorphous-silicon thin film transistor and the polycrystalline silicon thin film transistor, but also has advantages such as high visible light transmittance, and therefore, it is very promising to be applied to the next-generation large-size, high-definition and high-frame frequency transparent display. A channel material used by the metal oxide thin film transistor mainly includes ZnO, In₂O₃, IGZO, ZTO, IZO, ITO, SnO₂, AZO, and the like.

A major problem of the metal oxide thin film transistor is that a generated semiconductor channel layer always has a high carrier concentration, such that a threshold voltage of the transistor is very low or is even a negative value (for an n-type device), that is, when a gate is in a zero-bias state, the device cannot be completely turned off. On the other hand, if the channel layer is manufactured as a high-resistance layer having a lower carrier concentration, parasitic resistances of source and drain parts will increase, and a process of adding another layer of low-resistance metal layer is required, which increases the complexity of the manufacturing process.

### SUMMARY

An objective of the present invention is directed to provide a method of manufacturing a thin film transistor, such that an active layer of the manufactured thin film transistor has a high carrier concentration at a source region and a drain region, and a channel region has a low carrier concentration in a zero-bias state.

A thin film transistor includes a gate electrode, a gate dielectric layer covering the gate electrode, a metal oxide semiconductor layer formed on the gate dielectric layer, the metal oxide semiconductor layer including a source region, a drain region, and a channel region located between the source region and the drain region, where: the source region, the drain region and the channel region are located on the same film layer, and the channel region has a carrier concentration lower than that of the source region and the drain region.

The method of manufacturing a thin film transistor includes the following steps:

providing a substrate, the substrate including a first surface and a second surface opposite to each other;

forming a gate electrode on the first surface of the substrate;

forming on the first surface of the substrate a gate dielectric layer covering the gate electrode;

forming a metal oxide semiconductor layer on the gate dielectric layer;

processing the metal oxide semiconductor layer to form a channel region exposed on the metal oxide semiconductor layer;

anode-oxidizing the channel region, such that the channel region has a first carrier concentration;

conducting photolithography and etching the metal oxide semiconductor layer to form an active region, the active region includes the channel region, and a source region and a drain region located at the two sides of the channel region, the source region and the drain region having a second carrier concentration, and the first carrier concentration being lower than the second carrier concentration; and

forming electrode wires of the source region, the drain region and the gate electrode, so as to form a thin film transistor.

The metal oxide semiconductor layer is a thin film, is generated by using a magnetron sputtering technology, and a material thereof is selected from ZnO, In₂O₃, IGZO, ZTO, IZO, ITO, SnO₂, AZO, SnO₂:Sb, SnO₂:F, and the like.

The processing the metal oxide semiconductor layer includes forming a dielectric protection layer on the metal oxide semiconductor layer, and conducting photolithography and etching the dielectric protection layer to expose the channel region.

The anode-oxidizing the channel region is conducted at the room temperature, so as to improve the resistivity of the channel region.

The anode-oxidizing the channel region uses a method of oxidizing in a constant current mode first and then oxidizing in a constant voltage mode, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed.

In the present invention, by anode-oxidizing the channel region, the channel region is changed into a high-resistance region having a low carrier concentration, and by means of this processing method, it is unnecessary to provide a process of adding another layer of low-resistance metal layer. Semiconductor materials of the source region, the drain region and the channel region of the thin film transistor are formed by the same thin film process, without the need of another process of adding a source-drain metal layer, and therefore, the preparation process of the transistor is simplified.

### BRIEF DESCRIPTION OF THE DRAWINGS

The disclosure will become more fully understood from the detailed description given herein below for illustration only, and thus are not limitative of the disclosure, and wherein:

FIG. 1 is a schematic sectional structural diagram of a thin film transistor according to a specific embodiment of the present invention;

FIG. 2.1 to FIG. 2.8 sequentially show major process steps of a method of manufacturing a thin film transistor according to a specific embodiment of the present invention, where:

FIG. 2.1 schematically shows process steps of forming a gate electrode;

FIG. 2.2 schematically shows process steps of forming a gate dielectric layer;

FIG. 2.3 schematically shows process steps of forming a metal oxide semiconductor layer;

FIG. 2.4 shows process steps of depositing a dielectric protection layer;

FIG. 2.5 schematically shows process steps of patterning a dielectric protection layer to expose a channel region and anode-oxidizing the channel region;

FIG. 2.6 schematically shows process steps of patterning a metal oxide semiconductor layer and a dielectric protection layer to form an active region;

FIG. 2.6 schematically shows process steps of depositing a passivation layer and opening a contact hole; and

FIG. 2.8 shows process steps of forming wires of a source region, a drain region and a gate electrode;

FIG. 3.1 to FIG. 3.7 sequentially show major process steps of a method of manufacturing a thin film transistor according to another specific embodiment of the present invention, where:

FIG. 3.1 shows process steps of forming a gate electrode;

FIG. 3.2 shows process steps of forming a gate dielectric layer;

FIG. 3.3 schematically shows process steps of forming a metal oxide semiconductor layer;

FIG. 3.4 schematically shows process steps of defining a photoresist pattern and anode-oxidizing a channel region;

FIG. 3.5 schematically shows process steps of patterning a metal oxide semiconductor layer to form an active region;

FIG. 3.6 schematically shows process steps of depositing a passivation layer and opening a contact hole; and

FIG. 3.7 schematically shows process steps of depositing and patterning a source-drain metal layer;

FIG. 4.1 to FIG. 4.7 sequentially show major process steps of a method of manufacturing a thin film transistor according to another specific embodiment of the present invention, where:

FIG. 4.1 shows process steps of forming a gate electrode;

FIG. 4.2 shows process steps of growing a gate dielectric layer;

FIG. 4.3 schematically shows process steps of forming a metal oxide semiconductor layer;

FIG. 4.4 schematically shows process steps of coating a negative photoresist on a front surface, exposing and defining a photoresist pattern at a back surface, and anode-oxidizing a channel region;

FIG. 4.5 schematically shows process steps of patterning a metal oxide semiconductor layer to form an active region;

FIG. 4.6 schematically shows process steps of depositing a passivation layer and opening a contact hole; and

FIG. 4.7 schematically shows process steps of depositing and patterning a source-drain metal layer;

FIG. 5.1 to FIG. 5.8 sequentially show major process steps of a method of manufacturing a thin film transistor according to another specific embodiment of the present invention, where:

FIG. 5.1 shows process steps of forming a gate electrode;

FIG. 5.2 shows process steps of growing a gate dielectric layer;

FIG. 5.3 schematically shows process steps of forming a metal oxide semiconductor layer;

FIG. 5.4 shows process steps of depositing a dielectric protection layer;

FIG. 5.5 schematically shows process steps of coating a negative photoresist on a front surface, exposing at a back surface, conducting photolithography on a dielectric protection layer, and anode-oxidizing a channel region;

FIG. 5.6 schematically shows process steps of patterning a metal oxide semiconductor layer to form an active region;

FIG. 5.7 schematically shows process steps of depositing a passivation layer and opening a contact hole; and

FIG. 5.8 schematically shows process steps of depositing and patterning a source-drain metal layer; and

FIG. 6.1 to FIG. 6.9 sequentially show major process steps of a method of manufacturing a thin film transistor according to another specific embodiment of the present invention, where:

FIG. 6.1 shows process steps of forming a gate electrode;

FIG. 6.2 shows process steps of growing a gate dielectric layer;

FIG. 6.3 schematically shows process steps of forming a metal oxide semiconductor layer;

FIG. 6.4 schematically shows process steps of coating a positive photoresist on a front surface, exposing at a back surface, and conducting development to form a photoresist pattern;

FIG. 6.5 shows process steps of depositing a dielectric protection layer;

FIG. 6.6 schematically shows process steps of obtaining a dielectric protection layer pattern through peeling, and anode-oxidizing a channel region;

FIG. 6.7 schematically shows process steps of patterning a metal oxide semiconductor layer to form an active region;

FIG. 6.8 schematically shows process steps of depositing a passivation layer and opening a contact hole; and

FIG. 6.9 schematically shows process steps of depositing and patterning a source-drain metal layer.

### DETAILED DESCRIPTION

FIG. 1 is a schematic sectional structural diagram of a thin film transistor according to the present invention. The thin film transistor is formed on a glass substrate or flexible substrate 1.

The thin film transistor includes a gate electrode 2, a gate dielectric layer 3, and a metal oxide semiconductor layer 4; an active region is formed on the metal oxide semiconductor layer 4, and the active region includes a channel region 5, a source region 6 and a drain region 7. The gate electrode 2 is located on the substrate 1, the gate dielectric layer 3 is located on the substrate 1 and the gate electrode 2, and covers the gate electrode 2; and the metal oxide semiconductor layer 4 is formed on the gate dielectric layer 3. The channel region 5 is a middle part of an active region, located on the gate dielectric layer 3 covering the gate electrode 2, and corresponding to the gate electrode 2; and the source region 6 and the drain region 7 are located at two sides of the channel region 5, and are respectively connected to the channel region 5.

The gate electrode 2 may be a metal thin film, such as chromium, molybdenum, titanium, hafnium, tantalum, or aluminum, formed by a magnetron sputtering or thermal evaporation method; and may also be a transparent conductive thin film, such as ITO, formed by a magnetron sputtering method. The thickness of the gate electrode 2 is generally 100-300 nm. The gate dielectric layer 3 may be an insulating medium, such as silicon nitride and silicon oxide, formed by a chemical vapor deposition (PECVD) method; and may also be a metal oxide, such as aluminum oxide, tantalum oxide or hafnium oxide, formed by a magnetron sputtering or anode-oxidizing method. The thickness of the gate dielectric 3 is generally 100-400 nm. The metal oxide semiconductor active layer 4 is made of an amorphous or polycrystalline metal oxide semiconductor material, such as ZnO, In₂O₃, IGZO, ZTO, IZO, ITO, SnO₂, AZO, SnO₂:Sb, and SnO₂:F, formed by a magnetron sputtering method, and has a thickness of 50-200 nm; the channel region 5 is a middle part of the active layer 4, has a very low carrier concentration in a non-biased state, and presents a high-resistance state. The source region 6 and the drain region 7 are two end parts of the active layer 4, have a high carrier concentration, and are in a low-resistance state.

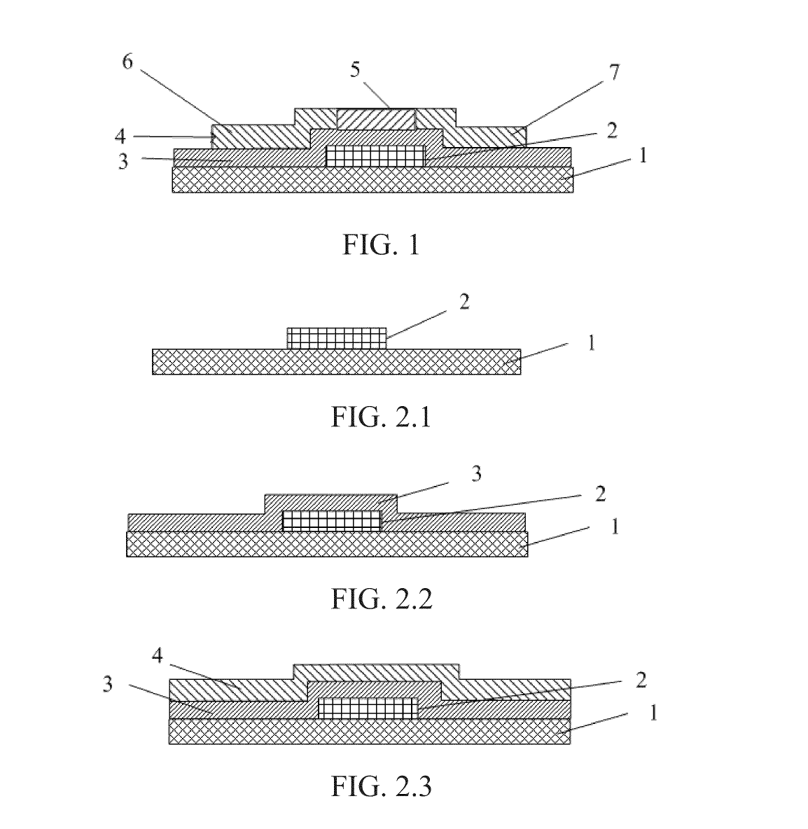

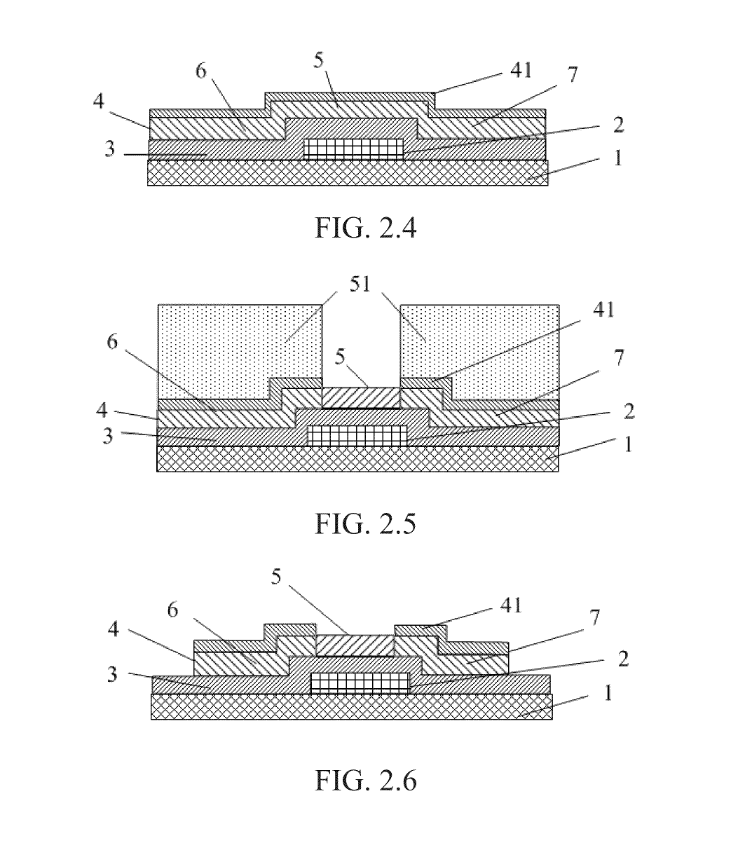

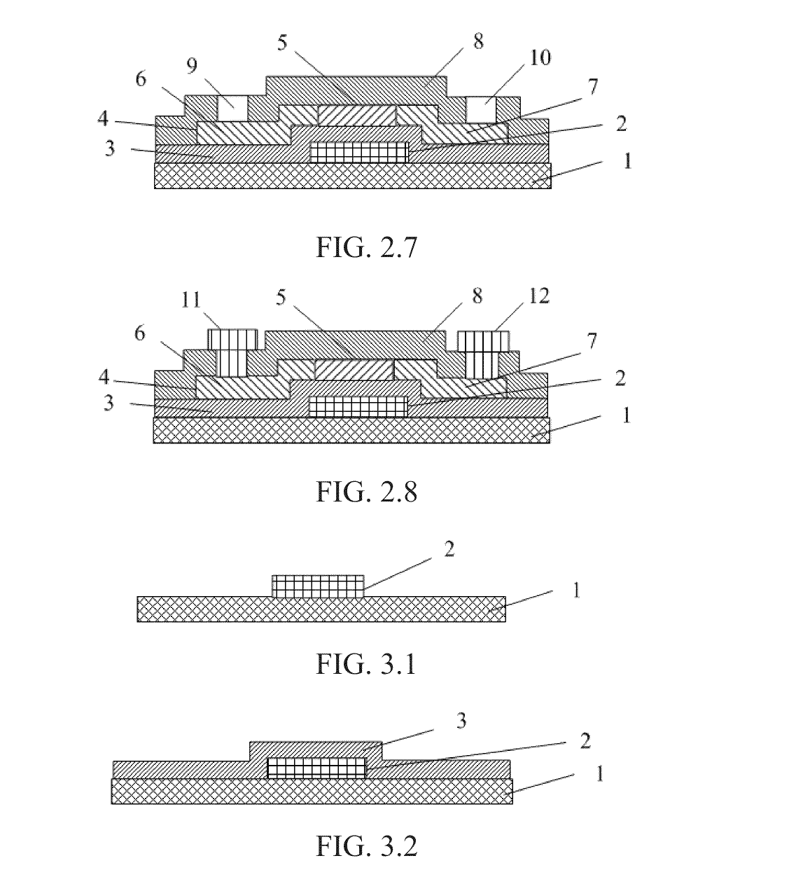

A specific embodiment of a method of manufacturing a thin film transistor is shown in FIG. 2.1 to FIG. 2.8, and includes the following steps:

As shown in FIG. 2.1, a used substrate 1 may be a high temperature resistant substrate, for example, a glass substrate, and may also be a non-high temperature resistant flexible substrate, for example, a plastic substrate. A metal thin film, such as chromium, molybdenum, titanium, hafnium, tantalum, or aluminum, or a transparent conductive thin film having a thickness of 100-300 nm is grown on the substrate 1, and photolithography and etching are conducted to form a gate electrode 2.

As shown in FIG. 2.2, a layer of insulating medium, such as silicon nitride and silicon oxide, having a thickness of 100-300 nm is grown on the substrate 1 by using a plasma enhancement chemical vapor deposition (PECVD) method, and covers the gate electrode 2 to serve as a gate dielectric layer 3; or a layer of high-k (dielectric constant) medium, such as hafnium oxide, tantalum oxide, aluminum oxide or a lamination thereof, having a thickness of 100-300 nm is grown by using a magnetron sputtering or anode-oxidizing method, and covers the gate electrode 2 to serve as a gate dielectric layer 3.

As shown in FIG. 2.3, a metal oxide semiconductor layer 4 having a thickness of 50-200 nm is grown on the gate dielectric layer 3, which is an amorphous or polycrystalline metal oxide semiconductor material, for example, a common metal oxide semiconductor thin film material such as ZnO and In₂O₃, and may also be a highly-conductive oxide semiconductor thin film such as ITO or AZO, and the semiconductor layer may be deposited by using a magnetron sputtering method. When it is IGZO, a sputtering gas pressure is 0.5-2.5 Pa, and the gas is pure argon. In this case, the whole generated metal oxide semiconductor layer 4 becomes a low-resistance material having a high carrier concentration due to generation of a large amount of oxygen vacancies. When it is ITO, a target used is an ITO ceramic target, and a sputter atmosphere generally uses pure argon or a mixed gas of argon and a small amount of oxygen, and generally feeding a small amount of oxygen may improve the structure and performance of an ITO thin film, so as to obtain a low-resistance and high-transmittance ITO thin film. If a material having a lower resistance is required, it may be undergone a thermal treatment in an oxygen-free environment, for example, it may be processed in hydrogen, nitrogen, or vacuum, and a processing temperature should be lower than the maximum temperature that is tolerable by the substrate 1, such that the metal oxide semiconductor layer 4 becomes a low-resistance material having a high carrier concentration, so as to meet a requirement of a source and drain regions on a high carrier concentration, thereby reducing the parasitic resistance of the source and drain regions.

As shown in FIG. 2.4 and FIG. 2.5, a dielectric protection layer 41 of a silicon nitride thin film having a thickness of 50 nm is grown by using a PECVD method, a photoresist layer 51 is coated on the dielectric protection layer 41, and photolithography and etching are conducted thereon, so as to expose a channel region 5 on the metal oxide semiconductor layer 4, and other parts are covered and protected by the dielectric protection layer 41. The channel region 5 is anode-oxidized at the room temperature, and the anode-oxidizing process uses a method of oxidizing in a constant current mode first and then oxidizing in a constant voltage mode, that is, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed. Merely the channel region 5 is not covered during the oxidization process, the channel region 5 is exposed to a solution to be anode-oxidized, and the concentration of oxygen vacancies is reduced to turn into a low carrier concentration, and since the source and drain regions are covered, the concentration of oxygen vacancies is not affected by the anode-oxidization. Therefore, the carrier concentration of the channel region is changed to be lower than the carrier concentration of the source region 6 and the drain region 7.

The anode-oxidizing process is conducted at a constant pressure and room temperature, is a low-temperature process having a simple operation and low cost, and is applicable to batch production. The anode-oxidizing process, controlled by a voltage applied between electrodes, has a good repeatability, so that the controllability of the device characteristics is greatly improved.

As shown in FIG. 2.6, photolithography and etching are conducted on the dielectric protection layer 41 and the metal oxide semiconductor layer 4 under the dielectric protection layer, so as to form an active region of the transistor, and the active region includes a channel region 5, and a source region 6 and drain region 7 located at two sides of the channel region 5. The source region 6 and the drain region 7 are not anode-oxidized, and therefore, the carrier concentration thereof is higher than the carrier concentration of the channel region 5.

As shown in FIG. 2.7, a silicon nitride layer 8 having a thickness of 100-300 nm is deposited by using a PECVD or magnetron sputtering method to serve as a passivation dielectric layer, and photolithography and etching are conducted to form contact holes 9 and 10 of the electrodes.

As shown in FIG. 2.8, a metal aluminum film having a thickness of 100-300 nm is deposited by using a magnetron sputtering method, and photolithography and etching are conducted to form a metal extraction electrode and an interconnection wire 11 and 12 of each electrode of the thin film transistor. The electrode connection wires of the source region, the drain region and the gate electrode may be thin films, which are generally made of a common metal material, such as chromium, molybdenum, titanium, or aluminum, and may also be transparent conductive thin films, such as ITO.

In the present invention, by anode-oxidizing the channel region, the channel region is changed into a high-resistance region having a low carrier concentration, and by means of this processing method, it is unnecessary to provide a process of adding a layer of low-resistance metal layer. Semiconductor materials of the source region, the drain region and the channel region of the thin film transistor are formed by the same thin film process, without the need of another process of adding a source-drain metal layer, and therefore, the preparation process of the transistor is simplified.

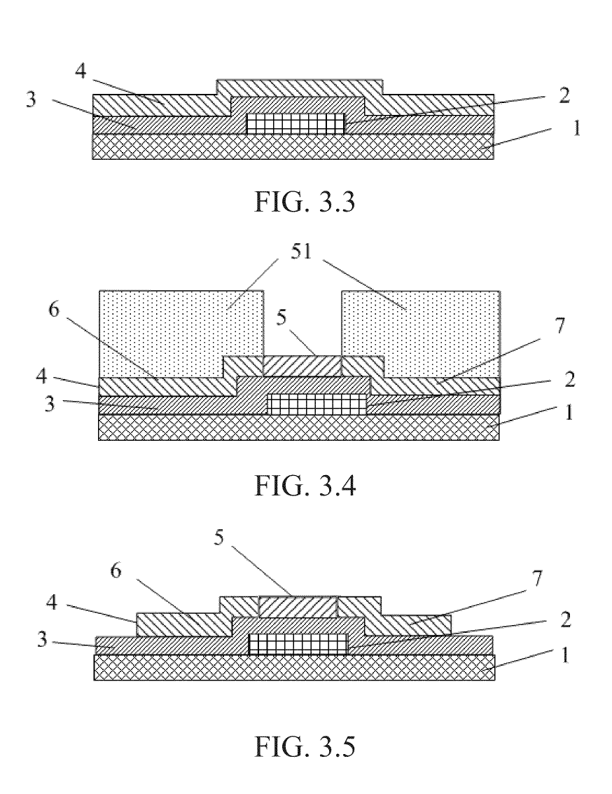

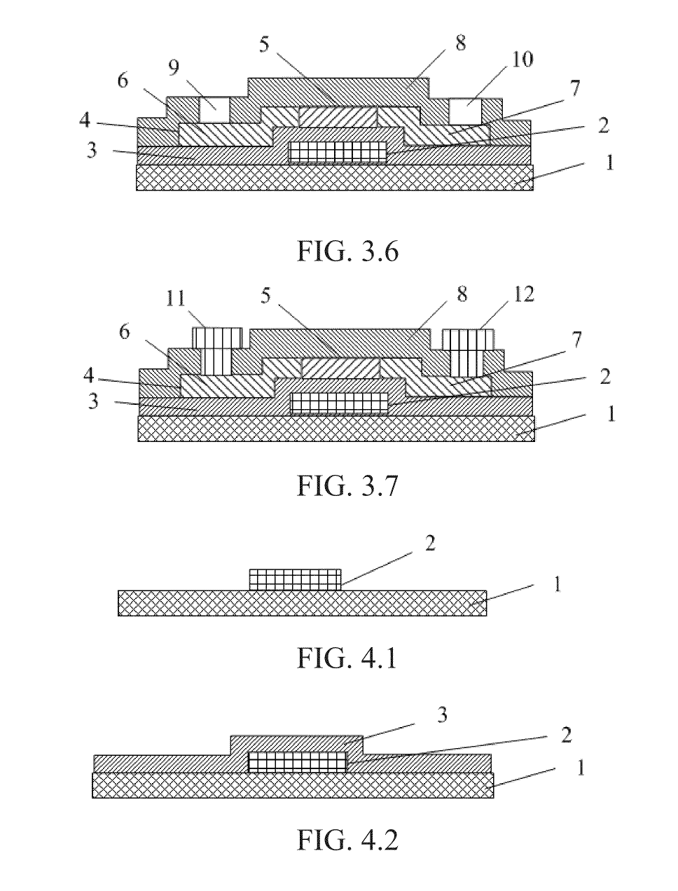

Another specific embodiment of a method of manufacturing a thin film transistor is shown in FIG. 3.1 to FIG. 3.7, and includes the following steps:

As shown in FIG. 3.1, the substrate 1 may be a high temperature resistant substrate, for example, a glass substrate, and may also be a non-high temperature resistant flexible substrate, for example, a plastic substrate. A metal thin film, such as such as chromium, molybdenum, titanium, or aluminum, or a transparent conductive thin film having a thickness of 100-300 nm is grown on the substrate 1, and photolithography and etching are conducted to form a gate electrode 2.

As shown in FIG. 3.2, a layer of insulating medium, such as silicon nitride and silicon oxide, having a thickness of 100-300 nm is grown on the substrate 1 by using a PECVD method, and covers the gate electrode 2 to serve as a gate dielectric layer 3.

As shown in FIG. 3.3, a metal oxide semiconductor layer 4 having a thickness of 50-200 nm is grown on the gate dielectric layer 3, which is an amorphous or polycrystalline metal oxide semiconductor material, for example, a common metal oxide semiconductor thin film material such as ZnO and In₂O₃, and may also be a highly-conductive oxide semiconductor thin film such as ITO or AZO, and the semiconductor layer may be deposited by using a magnetron sputtering method. When it is IGZO, a sputtering gas pressure is 0.5-2.5 Pa, and the gas is pure argon. In this case, the whole generated metal oxide semiconductor layer 4 becomes a low-resistance material having a high carrier concentration due to generation of a large amount of oxygen vacancies. When it is ITO, a target used is an ITO ceramic target, and a sputter atmosphere generally uses pure argon or a mixed gas of argon and a small amount of oxygen, and generally feeding a small amount of oxygen may improve the structure and performance of an ITO thin film, so as to obtain a low-resistance and high-transmittance ITO thin film. If a material having a lower resistance is required, it may be undergone a thermal treatment in an oxygen-free environment, for example, it may be processed in hydrogen, nitrogen, or vacuum, and a processing temperature should be lower than the maximum temperature that is tolerable by the substrate 1.

As shown in FIG. 3.4, a photoresist layer 51 is coated on the metal oxide semiconductor layer 4, and exposure and development are conducted thereon so as to expose a channel region 5 on the metal oxide semiconductor layer 4, and other parts are covered and protected by the photoresist layer. The channel region is anode-oxidized at the room temperature, and the process uses a method of oxidizing in a constant current mode first and then oxidizing in a constant voltage mode, that is, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed. The channel region 5 is exposed to a solution to be anode-oxidized, and the concentration of oxygen vacancies is reduced to turn into a low carrier concentration, and rest parts are protected by the non-conductive photoresist from being oxidized.

As shown in FIG. 3.5, photolithography and etching are conducted on the metal oxide semiconductor layer 4, so as to form an active region of the transistor, and the active region includes a source region 6, a drain region 7 and the channel region 5.

As shown in FIG. 3.6, a silicon nitride layer 8 having a thickness of 100-300 nm is deposited by using a PECVD or magnetron sputtering method, and photolithography and etching are conducted to form contact holes 9 and 10 of the electrodes.

As shown in FIG. 3.7, a metal aluminum film having a thickness of 100-300 nm is deposited by using a magnetron sputtering method, and photolithography and etching are conducted to form a metal extraction electrode and an interconnection wire 11 and 12 of each electrode of the thin film transistor.

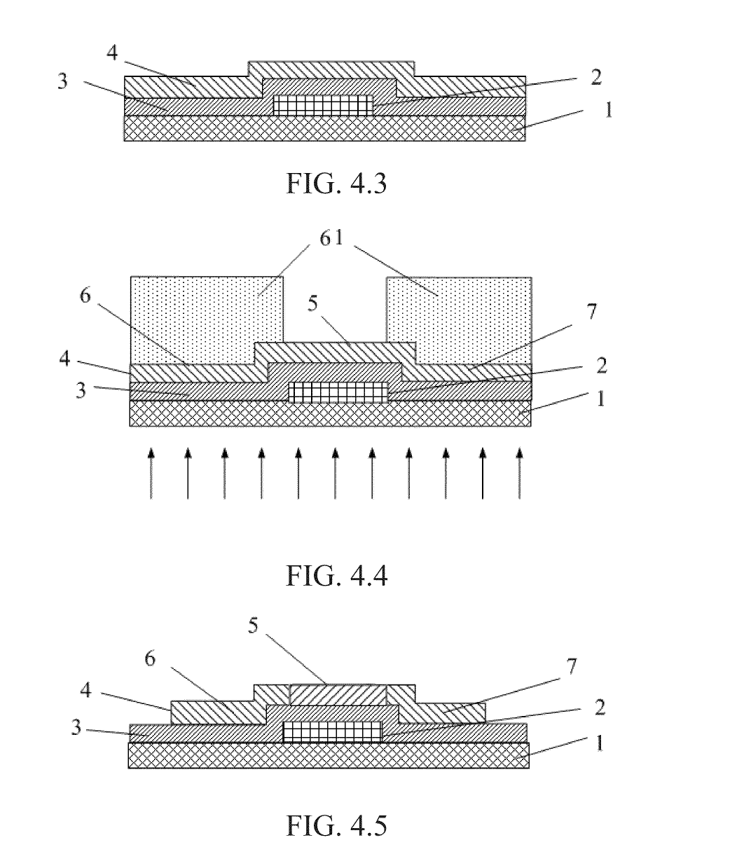

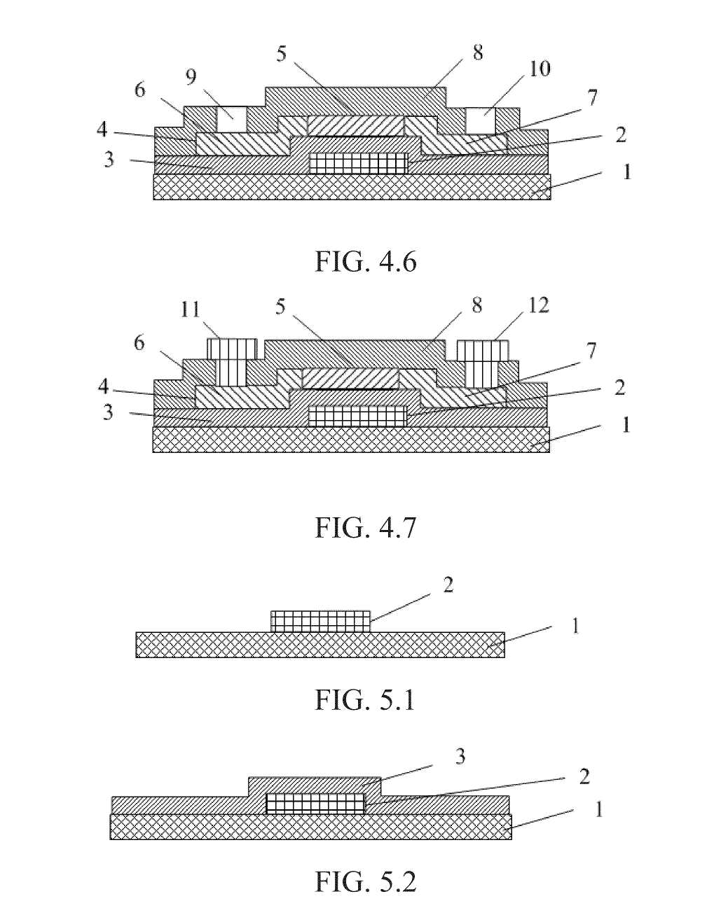

Another specific embodiment of a method of manufacturing a thin film transistor is shown in FIG. 4.1 to FIG. 4.7, and includes the following steps:

As shown in FIG. 4.1, the substrate 1 may be a high temperature resistant substrate, for example, a glass substrate, and may also be a non-high temperature resistant flexible substrate, for example, a transparent plastic substrate. A metal thin film, such as such as chromium, molybdenum, titanium, or aluminum, having a thickness of 100-300 nm is grown on the substrate 1, and photolithography and etching are conducted to form a gate electrode 2.

As shown in FIG. 4.2, a layer of insulating medium, such as silicon nitride and silicon oxide, having a thickness of 100-300 nm is grown on the substrate 1 by using a PECVD method, and covers the gate electrode 2 to serve as a gate dielectric layer 3.

As shown in FIG. 4.3, a metal oxide semiconductor layer 4 having a thickness of 50-200 nm is grown on the gate dielectric layer 3, which is an amorphous or polycrystalline metal oxide semiconductor material, for example, a common metal oxide semiconductor thin film material such as ZnO and In₂O₃, and may also be a highly-conductive oxide semiconductor thin film such as ITO or AZO, and the semiconductor layer may be deposited by using a magnetron sputtering method. When it is IGZO, a sputtering gas pressure is 0.5-2.5 Pa, and the gas is pure argon. In this case, the whole generated metal oxide semiconductor layer 4 becomes a low-resistance material having a high carrier concentration due to generation of a large amount of oxygen vacancies. When it is ITO, a target used is an ITO ceramic target, and a sputter atmosphere generally uses pure argon or a mixed gas of argon and a small amount of oxygen, and generally feeding a small amount of oxygen may improve the structure and performance of an ITO thin film, so as to obtain a low-resistance and high-transmittance thin film. If a material having a lower resistance is required, it may be undergone a thermal treatment in an oxygen-free environment, for example, it may be processed in hydrogen, nitrogen, or vacuum, and a processing temperature should be lower than the maximum temperature that is tolerable by the substrate 1.

As shown in FIG. 4.4, a negative photoresist layer is coated on the metal oxide semiconductor layer 4, exposure is conducted on a back surface of the substrate 1 by using the gate electrode as a mask, and in this case, the gate electrode 2 at the bottom is used as the mask, and development is conducted thereon; since the photoresist layer not blocked by the gate electrode 2 at the bottom as a mask is exposed and is insoluble to a developing solution, the photoresist layer blocked by the gate electrode 2 is not exposed and then dissolved in the developing solution, so as to form a photoresist pattern 61, such that the channel region 5 in the middle part of the metal oxide semiconductor layer 4 is exposed and self-aligned with the gate electrode, and other parts are covered and protected by the photoresist layer. The channel region is anode-oxidized at the room temperature, and the process uses a method of oxidizing in a constant current mode first and then oxidizing in a constant voltage mode, that is, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed. The channel region 5 is exposed to a solution to be anode-oxidized, and the concentration of oxygen vacancies is reduced to turn into a low carrier concentration, and rest parts are protected by the non-conductive photoresist from being oxidized.

As shown in FIG. 4.5, photolithography and etching are conducted on the metal oxide semiconductor layer 4, so as to form an active region of the transistor, and the active region includes a source region 6, a drain region 7 and the channel region 5.

As shown in FIG. 4.6, a silicon nitride layer 8 having a thickness of 100-300 nm is deposited by using a PECVD or magnetron sputtering method, and photolithography and etching are conducted to form contact holes 9 and 10 of the electrodes.

As shown in FIG. 4.7, a metal aluminum film having a thickness of 100-300 nm is deposited by using a magnetron sputtering method, and photolithography and etching are conducted to form a metal extraction electrode and an interconnection wire 11 and 12 of each electrode of the thin film transistor.

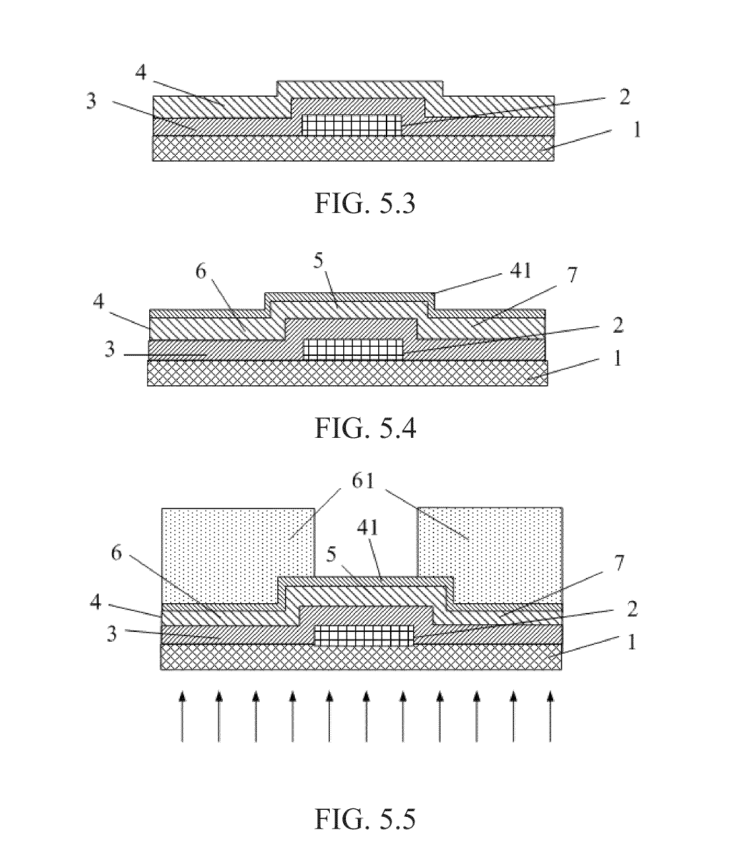

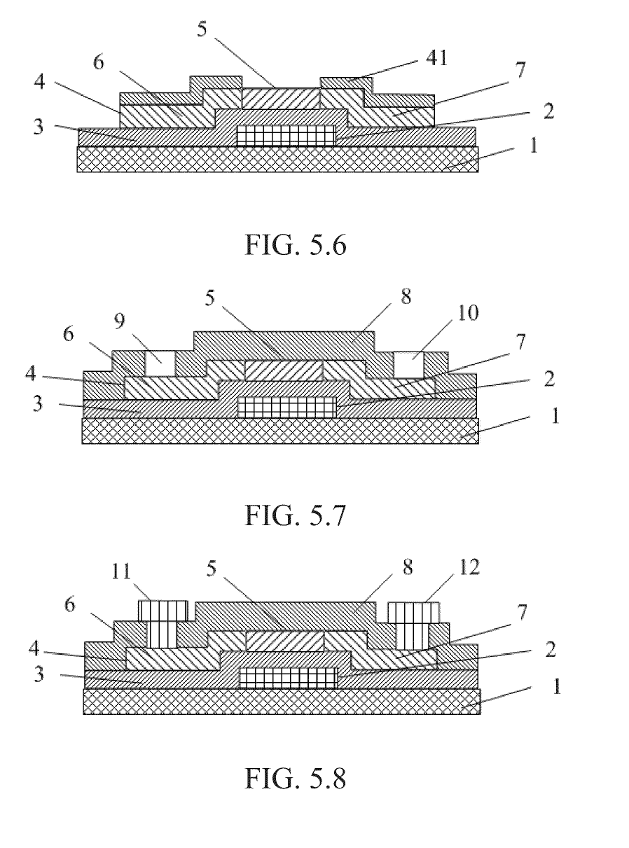

Another specific embodiment of a method of manufacturing a thin film transistor is shown in FIG. 5.1 to FIG. 5.8, and includes the following steps:

As shown in FIG. 5.1, the substrate 1 may be a high temperature resistant substrate, for example, a glass substrate, and may also be a non-high temperature resistant flexible substrate, for example, a transparent plastic substrate. A metal thin film, such as such as chromium, molybdenum, titanium, or aluminum, having a thickness of 100-300 nm is grown on the substrate 1, and photolithography and etching are conducted to form a gate electrode 2.

As shown in FIG. 5.2, a layer of insulating medium, such as silicon nitride and silicon oxide, having a thickness of 100-300 nm is grown on the substrate 1 by using a PECVD method, and covers the gate electrode 2 to serve as a gate dielectric layer 3.

As shown in FIG. 5.3, a metal oxide semiconductor layer 4 having a thickness of 50-200 nm is grown on the gate dielectric layer 3, which is an amorphous or polycrystalline metal oxide semiconductor material, for example, a common metal oxide semiconductor thin film material such as ZnO and In₂O₃, and may also be a highly-conductive oxide semiconductor thin film such as ITO or AZO, and the semiconductor layer may be deposited by using a magnetron sputtering method. When it is IGZO, a sputtering gas pressure is 0.5-2.5 Pa, and the gas is pure argon. In this case, the whole generated metal oxide semiconductor layer 4 becomes a low-resistance material having a high carrier concentration due to generation of a large amount of oxygen vacancies. When it is ITO, a target used is an ITO ceramic target, and a sputter atmosphere generally uses pure argon or a mixed gas of argon and a small amount of oxygen, and generally feeding a small amount of oxygen may improve the structure and performance of an ITO thin film, so as to obtain a low-resistance and high-transmittance ITO thin film. If a material having a lower resistance is required, it may be undergone a thermal treatment in an oxygen-free environment, for example, it may be processed in hydrogen, nitrogen, or vacuum, and a processing temperature should be lower than the maximum temperature that is tolerable by the substrate 1.

As shown in FIG. 5.4 and FIG. 5.5, a dielectric protection layer 41 of a silicon nitride thin film having a thickness of 50 nm is grown by using a PECVD method, a photoresist layer is coated on the dielectric protection layer 41, exposure is conducted on a back surface of the substrate 1 by using the gate electrode as a mask, and in this case, the gate electrode 2 at the bottom is used as the mask, and development is conducted thereon; since the photoresist layer not blocked by the gate electrode 2 at the bottom as a mask is exposed and is insoluble to a developing solution, the photoresist layer blocked by the gate electrode 2 is not exposed and then dissolved in the developing solution, so as to form a photoresist pattern 61, and the dielectric protection film is etched according to the formed photoresist pattern 61, such that the channel region 5 in the middle part of the metal oxide semiconductor layer 4 is exposed, and other parts of the active region are still protected by the dielectric protection layer 41. The channel region is anode-oxidized at the room temperature, and the process uses a method of oxidizing in a constant current mode first and then oxidizing in a constant voltage mode, that is, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed. The channel region 5 is exposed to a solution to be anode-oxidized, and the concentration of oxygen vacancies is reduced to turn into a low carrier concentration, and rest parts are protected by the non-conductive photoresist from being oxidized.

As shown in FIG. 5.6, photolithography and etching are conducted on the metal oxide semiconductor layer 4, so as to form an active region of the transistor, and the active region includes a source region 6, a drain region 7 and the channel region 5.

As shown in FIG. 5.7, a silicon nitride layer 8 having a thickness of 100-300 nm is deposited by using a PECVD or magnetron sputtering method, and photolithography and etching are conducted to form contact holes 9 and 10 of the electrodes.

As shown in FIG. 5.8, a metal aluminum film having a thickness of 100-300 nm is deposited by using a magnetron sputtering method, and photolithography and etching are conducted to form a metal extraction electrode and an interconnection wire 11 and 12 of each electrode of the thin film transistor.

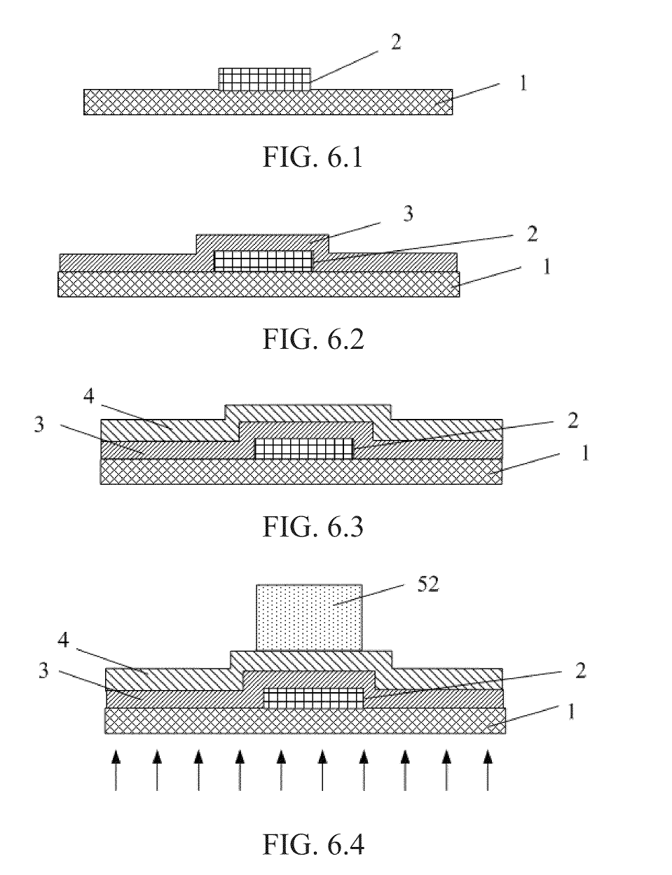

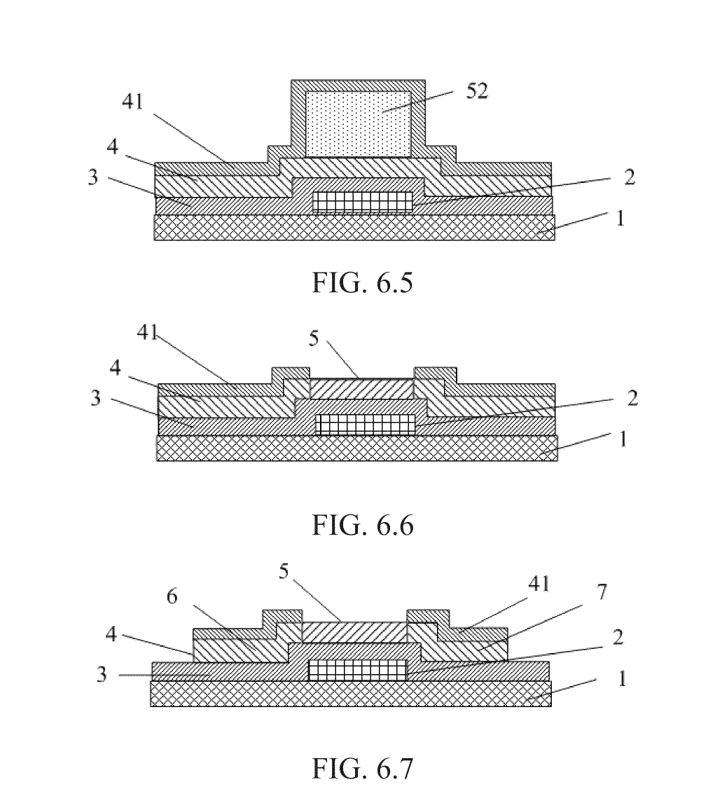

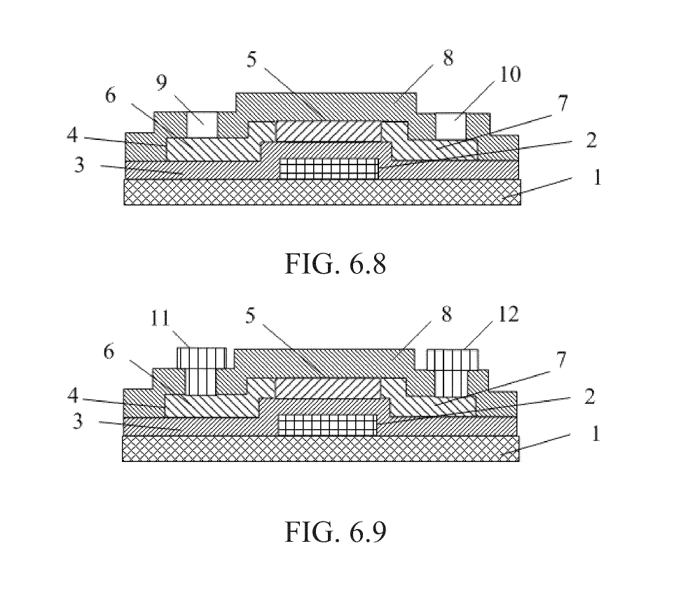

Another specific embodiment of a method of manufacturing a thin film transistor is shown in FIG. 6.1 to FIG. 6.9, and includes the following steps:

As shown in FIG. 6.1, the substrate 1 may be a high temperature resistant substrate, for example, a glass substrate, and may also be a non-high temperature resistant flexible substrate, for example, a transparent plastic substrate. A metal thin film, such as such as chromium, molybdenum, titanium, or aluminum, having a thickness of 100-300 nm is grown on the substrate 1, and photolithography and etching are conducted to form a gate electrode 2.

As shown in FIG. 6.2, a layer of insulating medium, such as silicon nitride and silicon oxide, having a thickness of 100-300 nm is grown on the substrate 1 by using a PECVD method, and covers the gate electrode 2 to serve as a gate dielectric layer 3.

As shown in FIG. 6.3, a metal oxide semiconductor layer 4 having a thickness of 50-200 nm is grown on the gate dielectric layer 3, which is an amorphous or polycrystalline metal oxide semiconductor material, for example, a common metal oxide semiconductor thin film material such as ZnO and In₂O₃, and may also be a highly-conductive oxide semiconductor thin film such as ITO or AZO, and the semiconductor layer may be deposited by using a magnetron sputtering method. When it is IGZO, a sputtering gas pressure is 0.5-2.5 Pa, and the gas is pure argon. In this case, the whole generated metal oxide semiconductor layer 4 becomes a low-resistance material having a high carrier concentration due to generation of a large amount of oxygen vacancies. When it is ITO, a target used is an ITO ceramic target, and a sputter atmosphere generally uses a mixed gas of argon and a small amount of oxygen, and generally feeding a small amount of oxygen may improve the structure and performance of an ITO thin film, so as to obtain a low-resistance and high-transmittance ITO thin film. If a material having a lower resistance is required, it may be undergone a thermal treatment in an oxygen-free environment, for example, it may be processed in hydrogen, nitrogen, or vacuum, and a processing temperature should be lower than the maximum temperature that is tolerable by the substrate 1.

As shown in FIG. 6.4, a positive photoresist layer is coated on the metal oxide semiconductor layer 4, exposure is conducted on a back surface of the substrate 1 by using the gate electrode as a mask, and in this case, the gate electrode 2 at the bottom is used as the mask, and development is conducted thereon; since the photoresist layer blocked by the gate electrode 2 is not exposed and is insoluble to a developing solution, the photoresist layer not blocked by the gate electrode 2 is exposed and then dissolved in the developing solution, so as to form a photoresist pattern 52.

As shown in FIG. 6.5 and FIG. 6.6, a dielectric protection layer 41 having a thickness of 20-100 nm is grown on the photoresist layer 52 and the metal oxide semiconductor layer 4, the dielectric protection layer 41 may be silicon oxide, silicon nitride or aluminum oxide, and may be generated by using a magnetron sputtering; a dielectric protection film is peeled to expose the channel region 5 in the middle part of the metal oxide semiconductor layer 4, and other parts of the active region are still protected by the dielectric protection layer 41. The channel region is anode-oxidized at the room temperature, and the process uses a method of oxidizing in a constant current mode first and then oxidizing in a constant voltage mode, that is, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed. The channel region 5 is exposed to a solution to be anode-oxidized, and the concentration of oxygen vacancies is reduced to turn into a low carrier concentration, and rest parts are protected by the non-conductive photoresist from being oxidized.

As shown in FIG. 6.7, photolithography and etching are conducted on the metal oxide semiconductor layer 4, so as to form an active region of the transistor, and the active region includes a source region 6, a drain region 7 and the channel region 5.

As shown in FIG. 6.8, a silicon nitride layer 8 having a thickness of 100-300 nm is deposited by using a PECVD or magnetron sputtering method, and photolithography and etching are conducted to form contact holes 9 and 10 of the electrodes.

As shown in FIG. 6.9, a metal aluminum film having a thickness of 100-300 nm is deposited by using a magnetron sputtering method, and photolithography and etching are conducted to form a metal extraction electrode and an interconnection wire 11 and 12 of each electrode of the thin film transistor.

The above content is further detailed descriptions of the present invention made in combination with specific implementation manners, and it cannot be considered that the specific implementations of the present invention merely limit to the descriptions. For a person of ordinary skill in the art of the present invention, various simple deduction or replacement may be made without departing from the spirit of the present invention.

1. A method of manufacturing a thin film transistor, comprising:
providing a substrate, the substrate comprising a first surface and a second surface opposite to each other;
forming a gate electrode on the first surface of the substrate;
forming on the first surface of the substrate a gate dielectric layer covering the gate electrode;
forming a metal oxide semiconductor layer on the gate dielectric layer;
processing the metal oxide semiconductor layer to form a channel region exposed on the metal oxide semiconductor layer;
anode-oxidizing the channel region, such that the channel region has a first carrier concentration;
conducting photolithography and etching the metal oxide semiconductor layer to form an active region, the active region comprising the channel region, and a source region and a drain region located at the two sides of the channel region, the source region and the drain region having a second carrier concentration, and the first carrier concentration being lower than the second carrier concentration; and
forming electrode wires of the source region, the drain region and the gate electrode, so as to form a thin film transistor.

2. The manufacturing method according to claim 1, wherein before processing the metal oxide semiconductor layer, the method further comprises conducting thermal treatment on the metal oxide semiconductor layer in an oxygen-free environment to improve the carrier concentration thereof.

3. The manufacturing method according to claim 1, wherein the processing the metal oxide semiconductor layer comprises first generating a dielectric protection layer on the metal oxide semiconductor layer, coating a photoresist, and conducting photolithography and etching the dielectric protection layer to expose the channel region.

4. The manufacturing method according to claim 1, wherein the processing the metal oxide semiconductor layer comprises directly coating a photoresist layer on the metal oxide semiconductor layer, and conducting photolithography to expose the channel region.

5. The manufacturing method according to claim 1, wherein the processing the metal oxide semiconductor layer comprises coating a negative photoresist layer on the metal oxide semiconductor layer, and conducting exposure and development on the second surface of the substrate by using the gate electrode as a mask to from a photoresist pattern, so as to expose the channel region.

6. The manufacturing method according to claim 1, wherein the processing the metal oxide semiconductor layer comprises forming a dielectric protection layer on the metal oxide semiconductor layer, coating a negative photoresist layer, conducting exposure and development on the second surface of the substrate by using the gate electrode as a mask to from a photoresist pattern, and then removing the dielectric protection layer on the channel region by using the photoresist pattern as a mask, so as to expose the channel region.

7. The manufacturing method according to claim 1, wherein the processing the metal oxide semiconductor layer comprises coating a positive photoresist layer on the metal oxide semiconductor layer, conducting exposure and development on the second surface of the substrate by using the gate electrode as a mask to from a photoresist pattern, forming a dielectric protection layer on the photoresist pattern, and then peeling the dielectric protection layer to expose the channel region.

8. The manufacturing method according to claim 1, wherein the anode-oxidizing the channel region is conducted at the room temperature.

9. The method of manufacturing a thin film transistor according to claim 1, wherein the anode-oxidizing the channel region uses a method of oxidizing in a constant current mode first and then oxidizing in a constant voltage mode, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed.

10. A thin film transistor, comprising a gate electrode, a gate dielectric layer covering the gate electrode, a metal oxide semiconductor layer formed on the gate dielectric layer, the metal oxide semiconductor layer comprising a source region, a drain region, and a channel region located between the source region and the drain region, wherein: the source region, the drain region and the channel region are located on the same film layer, and the channel region has a lower than the carrier concentration of the source region and the drain region.

11. The method of manufacturing a thin film transistor according to claim 8, wherein the anode-oxidizing the channel region uses a method of oxidizing in a constant current mode first and then oxidizing in a constant voltage mode, during the constant current, the current density is 0.02-2 mA/cm², and when the voltage rises to a preset value 10-300 V, the mode turns to the constant voltage mode for about an hour, and in this case, the current drops to be small enough, and the anode-oxidizing process is completed.
